(19) United States
(12) Patent Application Publication
(10) Pub. No.: US 2025/0311097 A1
(43) Pub. Date: Oct. 2, 2025

(54) WIRING SUBSTRATE

(71) Applicant: IBIDEN CO., LTD., Ogaki (JP)

(72) Inventors: Susumu KAGOHASHI, Ogaki (JP); Nobuhisa KURODA, Ibi-gun (JP); Toshihide MAKINO, Ibi-gun (JP)

(73) Assignee: IBIDEN CO., LTD., Ogaki (JP)

(21) Appl. No.: 19/091,003

(22) Filed: Mar. 26, 2025

(30) Foreign Application Priority Data
Mar. 27, 2024 (JP) 2024-051385

(51) Int. Cl. H05K 1/02; H05K 1/11; H05K 3/18

(52) U.S. Cl. CPC H05K 1/0298; H05K 1/116; H05K 3/181; H05K 2201/096; H05K 2201/10242; H05K 2201/2081

(57) ABSTRACT

A wiring substrate includes a build-up part including a conductor layer and an insulating layer, a solder resist layer formed in contact with a surface of the build-up part, and a metal post formed on the build-up part and protruding from the solder resist layer. The build-up part includes conductor layers including the conductor layer and insulating layers including the insulating layer such that the conductor layer includes a conductor pad, is formed on a surface of the solder resist layer and is in contact with a surface of the insulating layer forming the surface of the build-up part, and the metal post includes a base plating layer connected to the conductor pad of the conductor layer in the build-up part such that the base plating layer includes a penetrating portion formed in an opening of the solder resist layer and a pad portion protruding from the solder resist layer.

### CROSS-REFERENCE TO RELATED APPLICATIONS

The present application is based upon and claims the benefit of priority to Japanese Patent Application No. 2024-051385, filed Mar. 27, 2024, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2024-15869 describes a build-up wiring substrate without a core substrate. The entire contents of this publication are incorporated herein by reference.

### SUMMARY OF THE INVENTION

According to one aspect of the present invention, a wiring substrate includes a build-up part including a conductor layer and an insulating layer, a solder resist layer formed on the build-up part such that solder resist layer is in contact with a surface of the build-up part, and a metal post formed on the build-up part such that the metal post is protruding from the solder resist layer. The build-up part includes conductor layers including the conductor layer and insulating layers including the insulating layer such that the conductor layer includes a conductor pad, is formed on a surface of the solder resist layer and is in contact with a surface of the insulating layer forming the surface of the build-up part, and the metal post includes a base plating layer connected to the conductor pad of the conductor layer in the build-up part such that the base plating layer includes a penetrating portion formed in an opening of the solder resist layer and a pad portion protruding from the solder resist layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is an enlarged view of a portion (II) of the wiring substrate of FIG. 1;

FIG. 3 is a plan view illustrating an example of an overlapping state of a metal post, conductor pads, and a via conductor in according to an embodiment of the present invention;

FIG. 4 is an enlarged cross-sectional view illustrating a modified example of metal posts in the wiring substrate of FIG. 1;

FIG. 5A is a cross-sectional view illustrating an example of a wiring substrate during a manufacturing process according to an embodiment of the present invention;

FIG. 5B is a cross-sectional view illustrating an example of a wiring substrate during a manufacturing process according to an embodiment of the present invention;

FIG. 5C is a cross-sectional view illustrating an example of a wiring substrate during a manufacturing process according to an embodiment of the present invention;

FIG. 5D is a cross-sectional view illustrating an example of a wiring substrate during a manufacturing process according to an embodiment of the present invention;

FIG. 5E is a cross-sectional view illustrating an example of a wiring substrate during a manufacturing process according to an embodiment of the present invention;

FIG. 5F is a cross-sectional view illustrating an example of a wiring substrate during a manufacturing process according to an embodiment of the present invention;

FIG. 5G is a cross-sectional view illustrating an example of a wiring substrate during a manufacturing process according to an embodiment of the present invention;

FIG. 5H is a cross-sectional view illustrating an example of a wiring substrate during a manufacturing process according to an embodiment of the present invention;

FIG. 5I is a cross-sectional view illustrating an example of a wiring substrate during a manufacturing process according to an embodiment of the present invention;

FIG. 5J is a cross-sectional view illustrating an example of a wiring substrate during a manufacturing process according to an embodiment of the present invention;

FIG. 5K is a cross-sectional view illustrating an example of a wiring substrate during a manufacturing process according to an embodiment of the present invention;

FIG. 5L is a cross-sectional view illustrating an example of a wiring substrate during a manufacturing process according to an embodiment of the present invention;

FIG. 6 is a cross-sectional view illustrating an example of a wiring substrate according to a second embodiment of the present invention;

FIG. 7A is a cross-sectional view illustrating an example of a wiring substrate during a manufacturing process according to the second embodiment of the present invention; and

FIG. 7B is a cross-sectional view illustrating an example of a wiring substrate during a manufacturing process according to the second embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Structure of Wiring Substrate

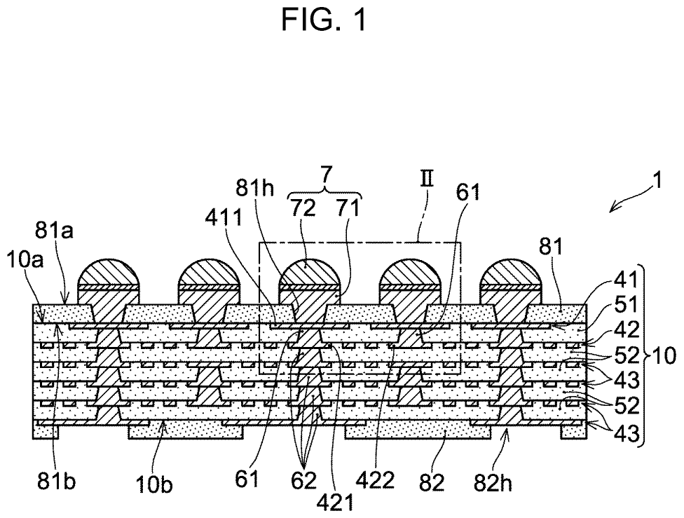

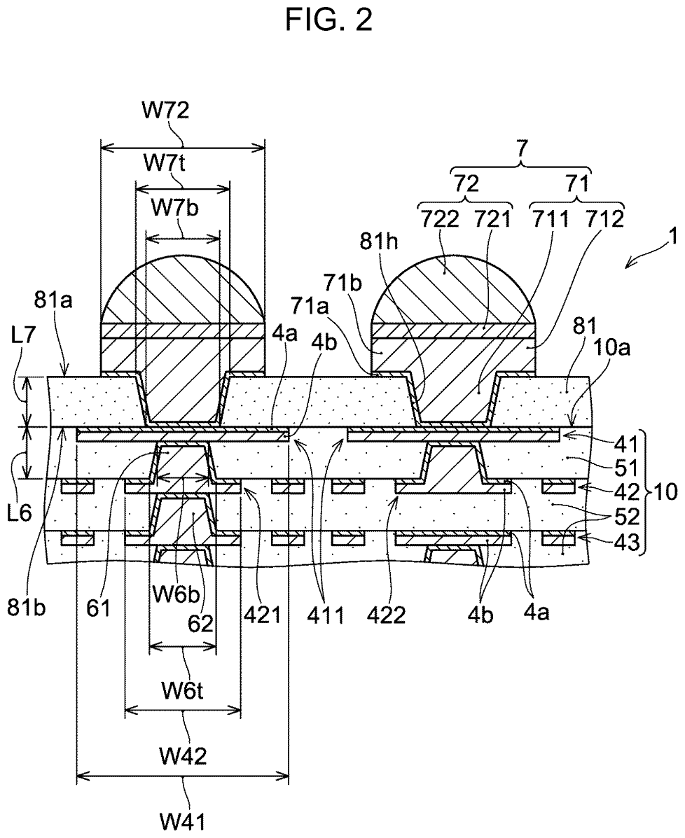

A wiring substrate according to an embodiment of the present invention is described with reference to the drawings. FIG. 1 illustrates a wiring substrate 1, which is an example of a wiring substrate according to an embodiment of the present invention. FIG. 2 illustrates an enlarged view of a portion (II) of the wiring substrate 1 in FIG. 1. A laminated structure of the wiring substrate of the embodiment is not limited to the laminated structure of the wiring substrate illustrated in the drawings, and the number of conductor layers and the number of insulating layers in the wiring substrate of the embodiment are not limited to the number of conductor layers and the number of insulating layers included in the wiring substrate illustrated in the drawings. The wiring substrate of the embodiment may include, in addition to the insulating layers and conductor layers included in the wiring substrate illustrated in the drawings, any number of insulating layers and conductor layers, and it is also possible that all of the insulating layers and conductor layers included in the wiring substrate illustrated in the drawings are not included.

As illustrated in FIG. 1, the wiring substrate 1 includes a build-up part 10 (first build-up part) having a first surface (10a) and a second surface (10b) facing opposite directions with respect to each other, a solder resist layer 81, and metal posts 7 protruding from the solder resist layer 81 in a direction opposite to the first surface (10a) of the build-up part 10. The metal posts 7 each include a base plating layer 71. The solder resist layer 81 is in contact with the first surface (10a) of the build-up part 10. The first surface (10a) and second surface (10b) of the build-up part 10 are two main surfaces of the build-up part 10 that are orthogonal to a thickness direction of the build-up part 10, and are two surfaces of the build-up part 10 facing opposite directions with respect to each other. The wiring substrate 1 of FIG. 1 further includes a solder resist layer 82. In the wiring substrate 1, the surface on the side where the solder resist layer 81 is provided is, for example, a component mounting surface on which a component (not illustrated) such as a semiconductor integrated circuit device is mounted.

The build-up part 10 is constituted by alternately laminated conductor layers and insulating layers. In the wiring substrate 1 of FIG. 1, the build-up part 10 includes insulating layers (51, 52), conductor layers (41-43), and via conductors (61, 62). In the build-up part 10, from the first surface (10a) in contact with the solder resist layer 81 toward the second surface (10b), the conductor layer 41 (first conductor layer), the insulating layer 51 (first insulating layer), and the conductor layer 42 (second conductor layer) are sequentially formed. Furthermore, on the conductor layer 42 and on the second surface (10b) side of the insulating layer 51, the insulating layers 52 and the conductor layers 43 are alternately formed, with a total of four pairs of insulating layers 52 and conductor layers 43 laminated. Among the via conductors (61, 62), the via conductors 61 (first via conductors) penetrate the insulating layer 51, connecting the conductor layer 41 and the conductor layer 42. Further, the via conductors 62 penetrate the insulating layers 52, either connecting the conductor layer 42 and a conductor layer 43 or connecting conductor layers 43 to each other.

Among the insulating layers (51, 52), the insulating layer 51 constitutes the first surface (10a) of the build-up part 10. Specifically, surfaces of the insulating layer 51 and the conductor layer 41 on the solder resist layer 81 side constitute the first surface (10a). On the other hand, surfaces of the insulating layer 52 and the conductor layer 43, which are farthest from the first surface (10a), on the opposite side with respect to the first surface (10a), constitute the second surface (10b) of the build-up part 10.

The conductor layer 41 is embedded in the insulating layer 51. A surface of the conductor layer 41 on the solder resist layer 81 side is exposed at the first surface (10a) and is in contact with a surface (81b) of the solder resist layer 81. The surface (81b) of the solder resist layer 81 is in contact with the first surface (10a) of the build-up part 10. In other words, the surface (81b) is a contact surface of the solder resist layer 81 with the first surface (10a). The insulating layer 51 and the conductor layer 41 are formed on the surface (81b) of the solder resist layer 81. On the other hand, the solder resist layer 82 covers the second surface (10b) of the build-up part 10.

The conductor layers (41-43) each include any conductor patterns. The conductor layer 41 includes conductor pads 411 (first conductor pads). The conductor layer 42 includes conductor pads (421, 422). The conductor pads 411 are conductor pads, called installation pads or mounting pads, used for connection with a component (not illustrated) such as a semiconductor integrated circuit device, mounted on the wiring substrate 1. The via conductors 61 are connected to the conductor pads 411. In other words, the conductor pads 411 are also so-called via landing pads for the via conductors 61.

The via conductors 61 connect the conductor pads 411 and the second conductor pads (421, 422). The conductor pads 421 and the conductor pads 422 are via pads for the via conductors 61 and are respectively integrally formed with the via conductors 61. In other words, the conductor pads (421, 422) are formed on a surface of the insulating layer 51 on the second surface (10b) side of the build-up part 10 and are connected to the via conductors 61. The conductor pads 421 are also via landing pads for the via conductors 62.

In the example of FIG. 1, the via conductors 61 are tapered toward the conductor pads 411. In other words, the via conductors 61 each have a conical shape such that the via conductors 61 gradually decrease in width toward the conductor pads 411. Therefore, the width of each of the via conductors 61 gradually decreases as it approaches the first surface (10a) side of the build-up part 10. The via conductors 62 are also tapered, similar to the via conductors 61, such that the width of each of the via conductors 62 gradually decreases toward the first surface (10a) side. Therefore, the width of each of the via conductors 62 gradually decreases as it approaches the first surface (10a) side of the build-up part 10.

The “width” of each of the via conductors 61 and the “width” of each of the via conductors 62 refer to a maximum distance between any two points on an outer perimeter of a cross section or end surface orthogonal to an axial direction of each via conductor. The via conductors 61 and the via conductors 62 can each have any planar shape. When the via conductors 61 and the via conductors 62 each have a substantially circular planar shape, the tapered via conductors 61 and via conductors 62 may gradually decrease in diameter toward the first surface (10a). The “planar shape” refers to a shape of an object in a plan view, and the “plan view” means viewing the object along a lamination direction of the conductor layers and insulating layers of the build-up part 10.

The build-up part 10, which includes the via conductors 61 tapered such that their width decreases toward the first surface (10a) side, is formed by sequentially forming individual conductor layers and individual insulating layers starting from the first surface (10a) side in contact with the solder resist layer 81. In other words, after the formation of each insulating layer, through holes for forming the via conductors 61 or via conductors 62 are formed in each insulating layer from the surface on the opposite side with respect to the first surface (10a) side, using a processing measure such as laser irradiation. Since power of the irradiated laser decreases with increasing distance from a light source, through holes each with a width decreasing toward the first surface (10a) side are formed. By filling the through holes with conductors, the via conductors 61 or via conductors 62 are formed. In this way, the build-up part 10 is formed by forming the conductor layers and insulating layers on the surface (81b) of the solder resist layer 81 starting from the first surface (10a) side. The via conductors 61 and via conductors 62 included in the build-up part 10 formed in this manner each have a width that decreases toward the first surface (10a) side, as illustrated in FIG. 1.

The wiring substrate 1 of the embodiment has the conductor layer 41 formed on the surface (81b) of the solder resist layer 81 in this manner. In other words, the conductor layer 41 is not formed on a metal film referred to as a seed layer, which is provided separately from the conductor layer 41 and used as a power feeding layer during the formation of the conductor layer 41. Therefore, between conductor patterns such as the conductor pads 411 of the conductor layer 41, insulation is already established at the time of completion of the formation of the conductor layer 41 in a manufacturing process of the wiring substrate 1. Consequently, after the formation of the conductor layer 41, an electrical inspection (short-circuit check) for short circuits between individual conductor patterns such as the conductor pads 411 can be performed. Further, it may be possible that at the time of completion of the formation of the conductor layer 42, a short-circuit check between the conductor patterns of the conductor layer 42, such as the conductor pads 421 connected to the conductor patterns of the conductor layer 41 via the via conductors 61, can be performed.

Similarly, it may be possible that at the time of completion of the formation of each conductor layer 43, a short-circuit check between the conductor patterns of each conductor layer 43, which are connected to the conductor patterns of the conductor layer 41 via the via conductors 62 and via conductors 61, can be performed. Then, at the time of completion of the formation of the build-up part 10, a short-circuit check between the conductor patterns of the conductor layer 43 exposed at the second surface (10b), which are electrically connected to the conductor patterns of the conductor layer 41, can be performed. Therefore, in the manufacturing of the wiring substrate of the embodiment, it is thought that sufficient short-circuit checks can be efficiently performed. It is inferred that the wiring substrate of the embodiment, in which such sufficient short-circuit checks can be efficiently performed, can have higher quality compared to a conventional wiring substrate.

The insulating layers (51, 52) are primarily formed of any insulating resin.

Examples of insulating resins used in the formation of the insulating layers (51, 52) include thermosetting resins such as epoxy resin, bismaleimide triazine resin (BT resin), or phenolic resin, as well as thermoplastic resins such as fluorine resin, liquid crystal polymer (LCP), fluorinated ethylene (PTFE) resin, polyester (PE) resin, and modified polyimide (MPI) resin. The insulating layers (51, 52) may each contain a filler made of, for example, silicon oxide, alumina, or mullite. Each resin listed as a material for the insulating layers (51, 52) is merely an example of a material that can form the insulating layers. Each insulating layer may be formed of any material capable of providing insulation to the conductor layers (41-43) and supporting the conductor layers (41-43).

Examples of materials for the solder resist layer 81 include polyimide resin, epoxy resin, and phenolic resin. Typically, epoxy resin is used as the material for the solder resist layer 81. The solder resist layer 82 may also be formed using polyimide resin, epoxy resin, or phenolic resin, which may be of the same type as or a different type from the resin used for the solder resist layer 81. The resin forming the solder resist layer 81 or the solder resist layer 82 may have photosensitive or thermosetting properties. The solder resist layer 82 has openings (82h) formed therein, and conductor pads of the conductor layer 43 are exposed in the openings (82h).

The conductor layers (41-43), the via conductors (61, 62), and the base plating layer 71 of the metal posts 7 are each formed of any metal having appropriate conductivity. For example, as a material constituting these components, copper or the like can be used. However, materials for the conductor layers (41-43), the via conductors (61, 62), and the base plating layer 71 of the metal posts 7 are not limited to copper only.

The conductor layers (41-43), the via conductors (61, 62), and the base plating layer 71 of the metal posts 7 are each constituted by, for example, an electroless plating film, a sputtering film, and an electrolytic plating film. The conductor layers (41-43), the via conductors (61, 62), and the base plating layer 71 of the metal posts 7 are depicted in FIG. 1 in a simplified manner as each having only one layer, but, as illustrated in FIG. 2, may each have a multilayer structure constituted by two or more metal films. However, it is also possible that the conductor layers (41-43), the via conductors (61, 62), and the base plating layer 71 of the metal posts 7 are each constituted by, for example, only one metal film, such as an electroless plating film.

As illustrated in FIG. 2, the conductor layer 41 includes a first metal film (4a) positioned on the first surface (10a) side of the build-up part 10, and a second metal film (4b) formed on a surface of the first metal film (4a) on the second surface (10b) side of the build-up part 10 (see FIG. 1). The first metal film (4a) of the conductor layer 41 is in contact with the surface (81b) of the solder resist layer 81. However, the surface (81b) of the solder resist layer 81 is not in contact with the second metal film (4b) of the conductor layer 41. The conductor layer 42 and the conductor layers 43, as well as the via conductors 61 and the via conductors 62, also each include a first metal film (4a) positioned on the first surface (10a) side of the build-up part 10, and a second metal film (4b) formed on a surface of the first metal film (4a) on the second surface (10b) side of the build-up part 10. The first metal film (4a) may be an electroless plating film or a sputtering film, and the second metal film (4b) may be an electrolytic plating film. Each conductor layer, such as the conductor layer 41, and each via conductor, constituted by such two metal films, can be efficiently formed to a desired thickness, and good adhesion between each conductor layer, or each via conductor, and the underlying insulating layer can be achieved.

The solder resist layer 81 has openings (81hl ) formed therein. The openings (81hl ) expose the conductor pads 411 of the conductor layer 41 from the solder resist layer 81. The metal posts 7 are formed on the conductor pads 411 exposed in the openings (81hl ). The base plating layer 71 of the metal posts 7 is connected to the conductor pads 411. In the example of FIGS. 1 and 2, the metal posts 7 include a top plating layer 72 in addition to the base plating layer. The top plating layer 72 is formed on a surface of the base plating layer 71 on the opposite side with respect to the solder resist layer 81. The base plating layer 71 includes a penetrating part 711 formed in the openings (81hl ) of the solder resist layer 81, and a pad part 712 protruding from a surface (81al ) of the solder resist layer 81. The surface (81al ) of the solder resist layer 81 is a surface of the solder resist layer 81 on the opposite side with respect to the build-up part 10.

The penetrating part 711 of the base plating layer 71 fills the openings (81hl ) of the solder resist layer 81. The pad part 712 of the base plating layer 71 covers the penetrating part 711 and, on the surface (81al ) of the solder resist layer 81, extends in a plan view beyond an outer edge of the openings (81h) by a predetermined length outward from the openings (81h). Therefore, a surface (upper surface) of the pad part 712 on the opposite side with respect to the solder resist layer 81, and a side surface of the pad part 712, are exposed and protrude from the surface (81a) of the solder resist layer 81. The base plating layer 71 is constituted by a third metal film (71a) formed on wall surfaces of the openings (81h) and on the surface (81a) of the solder resist layer 81, and a fourth metal film (71b) formed on the third metal film (71a). The third metal film (71a) may be an electroless plating film or a sputtering film, and the fourth metal film (71b) may be an electrolytic plating film.

In the wiring substrate 1 of the embodiment, since the metal posts 7 protruding from the surface (81a) of the solder resist layer 81 are formed on the conductor pads 411, it is thought that mounting a component onto the wiring substrate 1 is facilitated. In other words, for example, an electronic component, such as a semiconductor integrated circuit device, can be connected to the conductor pads 411 via the metal posts 7 protruding from the solder resist layer 81. Specifically, a component to be mounted onto the wiring substrate 1 can be placed on the top plating layer 72 of the metal posts 7. By mounting a component via the metal posts 7, it is possible to easily mount the component onto the wiring substrate 1 while suppressing a short circuit between adjacent conductor pads 411 caused by a bonding material such as solder.

Further, as described above, for example, the base plating layer 71 of the metal posts 7 is formed of a metal such as copper. The base plating layer 71 is preferably formed of a metal having a melting point higher than that of a bonding material, such as solder, for example, used for connecting a component (not illustrated) mounted on the metal posts 7. It is inferred that, compared to metal posts formed by filling openings in a solder resist with solder balls or solder paste or the like, a component can be mounted onto the wiring substrate 1 more stably. In other words, it is thought that a component mounted on the wiring substrate 1 can be stably connected to the conductor pads 411 with minimal tilt and with less variation in height.

The top plating layer 72 includes a lower layer 721 and an upper layer 722. The lower layer 721 is formed on the pad part 712 of the base plating layer 71 and covers the upper surface of the pad part 712. The upper layer 722 is formed on the lower layer 721 and covers an upper surface of the lower layer 721. The lower layer 721 is formed of, for example, a metal such as nickel. However, a material of the lower layer is not limited to nickel. Preferably, the lower layer 721 is formed of a metal different from the metal and material constituting the base plating layer 71.

On the other hand, the upper layer 722 may be formed of, for example, a metal such as solder that can function as a connection material between a component (not illustrated) mounted on the wiring substrate 1 and the metal posts 7. It is inferred that, by having the metal posts 7 that each include a plating film made of a material that functions as a connection material for a component, an amount of connection material is stabilized, enabling easy and stable mounting of a component. The material of the upper layer 722 is not limited to solder and may be gold or an alloy of gold with another metal such as palladium, for example.

In the wiring substrate 1 of the embodiment illustrated in FIGS. 1 and 2, the surface (upper surface) of the conductor pad 411 on the solder resist layer 81 side and the surface (upper surface) of the insulating layer 51 on the solder resist layer 81 side are substantially flush with each other. In other words, since both the conductor layer 41 and the insulating layer 51 are formed on the surface (81b) of the solder resist layer 81, steps are unlikely to form between the upper surfaces of the conductor pads 411 and the upper surface of the insulating layer 51, and the upper surfaces of the conductor layer 41 and the insulating layer 51 are likely to be flush with each other. Since the upper surfaces of the conductor layer 41 and the insulating layer 51 are substantially flush with each other, it is thought that voids are unlikely to form at an interface between the conductor layer 41 or the insulating layer 51 and the solder resist layer 81. Here, “substantially flush” means that a step between two surfaces to be compared is 0.5 μm or less.

The solder resist layer 81 can have any thickness. For example, the thickness of the solder resist layer 81 is about 15 μm to 30 μm. On the other hand, the insulating layer 51 and the insulating layers 52 may each have a thickness of about 7.5 μm to 15 μm.

Therefore, the thickness of the solder resist layer 81 may be greater than the thickness of each of the insulating layer 51 and the insulating layers 52. Even when a connection material such as solder, supplied on the metal posts 7, adheres to the solder resist layer 81, it is thought that a short circuit between the connection material and the conductor layer 41 can be more reliably prevented. The thickness of the insulating layer 51 is a distance from the surface of the conductor layer 41 on the second surface (10b) side of the build-up part 10 to the surface of the insulating layer 51 on the second surface (10b) side.

When the thickness of the solder resist layer 81 is greater than the thickness of the insulating layer 51, a length (L7) of the penetrating part 711 of the base plating layer 71 in a lamination direction of the conductor layer 41 and the insulating layer 51 is longer than a length (L6) of the via conductors 61. When the length (L7) of the penetrating part 711 is long, it is thought that a greater amount of stress caused by factors such as a difference in thermal expansion coefficients between a component (not illustrated) connected to the conductor pads 411 via the metal posts 7 and the wiring substrate 1 can be absorbed by the penetrating part 711. Further, when the length (L6) of the via conductors 61 is short, it is thought that the conductor pads 411 and the conductor pads 421 or conductor pads 422 can be connected with a lower conductor resistance.

The conductor pads 411, the metal posts 7, and the via conductors 61 preferably have appropriate size relationships with respect to dimensions of each respective part. In the example of FIG. 2, a width (bottom width) (W7b) of the penetrating part 711 of the base plating layer 71 at an interface with the conductor pads 411 is smaller than a width (top width) (W7t) of the penetrating part 711 at the surface (81a) of the solder resist layer 81. In particular, the penetrating part 711 in the example of FIG. 2 is tapered such that the width of the penetrating part 711 gradually decreases toward the conductor pads 411. On the other hand, a width (bottom width) (W6b) of each via conductor 61 at an interface with a conductor pad 411 is smaller than a width (top width) (W6t) of the via conductor 61 at an interface with a conductor pad 421 or a conductor pad 422. In particular, the via conductors 61 in the example of FIG. 2 are tapered such that the width of the via conductors 61 gradually decreases toward the conductor pads 411.

In other words, in the example of FIG. 2, the penetrating part 711 of the base plating layer 71 and the via conductors 61 are tapered in opposite directions to each other. It is thought that while a wide contact area is ensured between a component mounted on the wiring substrate 1 and the metal posts 7, the entire surface of the penetrating part 711 on the conductor pads 411 side can be more reliably in contact with the conductor pads 411. Further, it is thought that while a wide contact area is ensured with the conductor pads 421 or the conductor pads 422, the entire surfaces of the via conductors 61 on the conductor pads 411 side can be more reliably in contact with the conductor pads 411. The “width” of the penetrating part 711 refers to a maximum distance between any two points on an outer perimeter of a cross section or end surface of the penetrating part 711 that is orthogonal to the lamination direction of the build-up part 10. As will be described later, the “width” of each of the conductor pads 411 and the conductor pads 421 refers to a maximum distance between any two points on an outer perimeter of each conductor pad in a plan view.

Further, the width (W7t) of the penetrating part 711 of the base plating layer 71 at the surface (81a) of the solder resist layer 81 is larger than the width (W6t) of each via conductor 61 at the interface with a conductor pad 421 or a conductor pad 422. Due to the small width (W6t) of each via conductor 61 at the interface with a conductor pad 421 or a conductor pad 422, it may be possible to form wiring patterns at a high density in the conductor layer 42. On the other hand, it may be possible to ensure a large connection area between a component (not illustrated) mounted on the wiring substrate 1 and the metal posts 7.

Further, in the example of FIG. 2, a width (W41) of each of the conductor pads 411 is larger than a width (W72) of the pad part 712 of the base plating layer 71, and the width (W72) of the pad part 712 of the base plating layer 71 is larger than a width (W42) of each of the conductor pads 421 and conductor pads 422. The “width” of each of the conductor pads 411, the conductor pads 421, and the pad part 712 refers to a maximum distance between any two points on an outer perimeter of each conductor pad or the pad part 712 in a plan view.

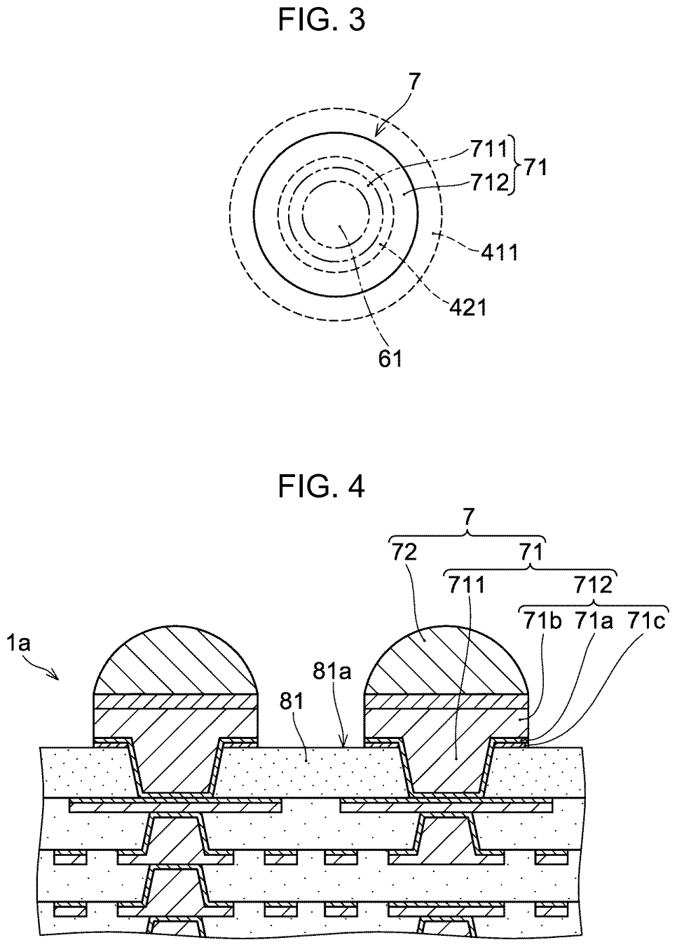

In particular, in the wiring substrate 1 of the embodiment illustrated in FIGS. 1 and 2, as illustrated in FIG. 3, the entire conductor pad 421 overlaps with the pad part 712 of the base plating layer in a plan view, and the entire pad part 712 overlaps with the conductor pad 411 in a plan view. Further, the entire via conductor 61 overlaps with the conductor pad 411 in a plan view, and the entire penetrating part 711 of the base plating layer 71 overlaps with the conductor pad 411 in a plan view. FIG. 3 schematically illustrates, in a plan view, an example of an overlapping state in a plan view of the base plating layer 71 of the metal posts 7, the conductor pads (411, 421), and the via conductors 61 in the wiring substrate 1 of FIGS. 1 and 2. In the wiring substrate 1, in a plan view, an area of each of the conductor pads 411 is larger than an area of the pad part 712 of the base plating layer 71 of each of the metal posts 7. And, the area of the pad part 712 is larger than an area of each of the conductor pads 421 and the conductor pads 422.

Due to the width (W41) of each of the conductor pads 411 being larger than the width (W72) of the pad part 712, even when some positional misalignment occurs in the metal posts 7, it may be possible for the metal posts 7 and the conductor pads 411 to be reliably in contact with each other. Further, since the width (W41) of each of the conductor pads 411 is small, it may be possible that a short circuit between the metal posts 7, where a connection material such as solder may be supplied, can be avoided. And, due to the width (W72) of the pad part 712 being larger than the width (W42) of each of the conductor pads (421, 422), in other words, due to the conductor pads (421, 422) being small, it may be possible that wiring patterns can be formed at a high density in the conductor layer 42.

In the conductor layers (42, 43) included in the build-up part 10, a minimum wiring width may be 1 μm or more and 3 μm or less, and a minimum inter-wiring distance may be 1 μm or more and 3 μm or less. Wiring patterns can be formed at a high density in the conductor layers (42, 43). Further, an aspect ratio of the wirings included in the conductor layers (42, 43) may be 2.0 or more and 4.0 or less. An aspect ratio of each via conductor 61 ((a distance between the conductor pad 411 and the conductor pad 421)/(the width of the via conductor 61 at an interface with the conductor pad 421)) may be 0.5 or more and 1.0 or less.

A minimum pitch of the metal posts 7 is, for example, 40 μm or more and 75 μm or less. In this case, an example of widths of each part of the metal posts 7, each conductor pad, and the via conductors 61 is illustrated below. The width (W42) of each of the conductor pads (421, 422) is 12 μm or more and 30 μm or less, and the top width (W6t) of each of the via conductors 61 is 6 μm or more and 12 μm or less. The width (W41) of each of the conductor pads 411 is 32 μm or more and 45 μm or less. And, the top width (W7t) of the penetrating part 711 of the base plating layer 71 of the metal posts 7 is 13 μm or more and 27 μm or less, and the width (W72) of the pad part 712 is 25 μm or more and 40 μm or less.

### Modified Example

FIG. 4 illustrates a portion of a wiring substrate (1a), which is a modified example of the wiring substrate 1 of the embodiment, corresponding to the portion illustrated in FIG. 2. The wiring substrate (1a) differs from the wiring substrate 1 illustrated in FIG. 2 only in that the pad part 712 of the base plating layer 71 of the metal posts 7 is constituted by a fifth metal film (71c) in addition to the third metal film (71a) and the fourth metal film (71b). Except for the fifth metal film (71c), the structure and structural elements of the wiring substrate (1a) are the same as those of the wiring substrate 1 of FIG. 2. Therefore, structural elements identical to those in the wiring substrate 1 are assigned in FIG. 4 the same reference numeral symbols as those used in FIG. 2 or are omitted as appropriate in FIG. 4, and repetitive descriptions thereof are omitted.

In the wiring substrate of the embodiment, the base plating layer 71 of the metal posts 7 may have a pad part 712 that includes a fifth metal film (71c), as in the wiring substrate (1a). An example of the fifth metal film (71c) is a sputtering film made of copper and titanium or the like. However, a metal film made of metals other than copper and titanium and formed using a method other than sputtering may also be used as the fifth metal film (71c). The fifth metal film (71c) is bonded to the surface (81a) of the solder resist layer 81, and the third metal film (71a) is formed on a surface of the fifth metal film (71c) on the opposite side with respect to the solder resist layer 81. Since the fifth metal film (71c) is interposed between the third metal film (71a) and the solder resist layer 81, adhesion between the metal posts 7 and the surface (81a) of the solder resist layer 81 may be high.

### Method for Manufacturing Wiring Substrate

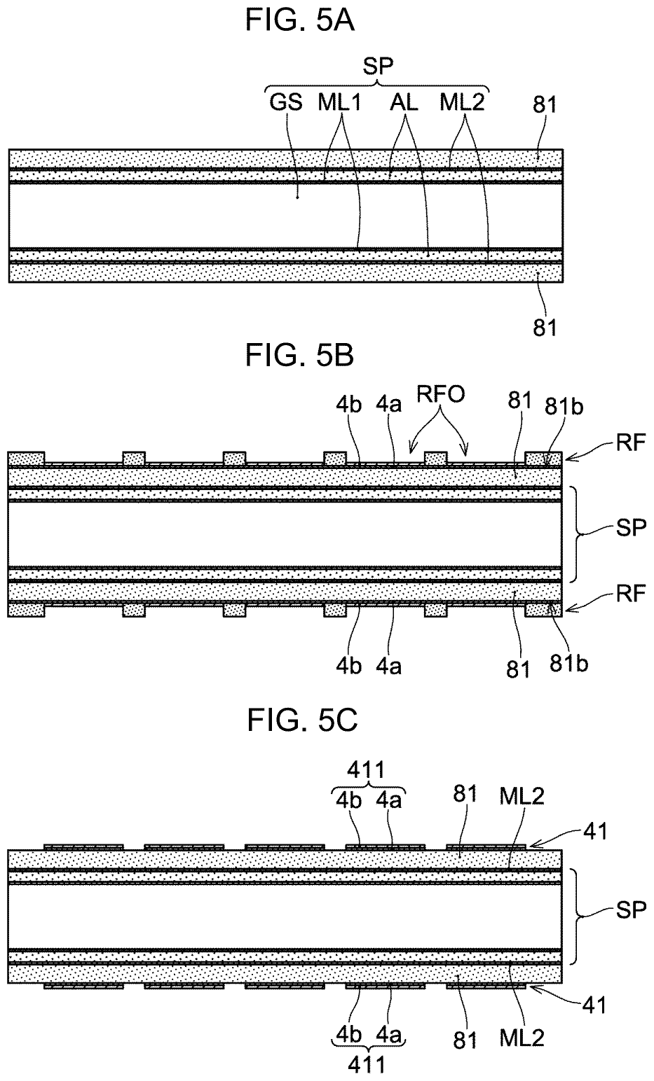

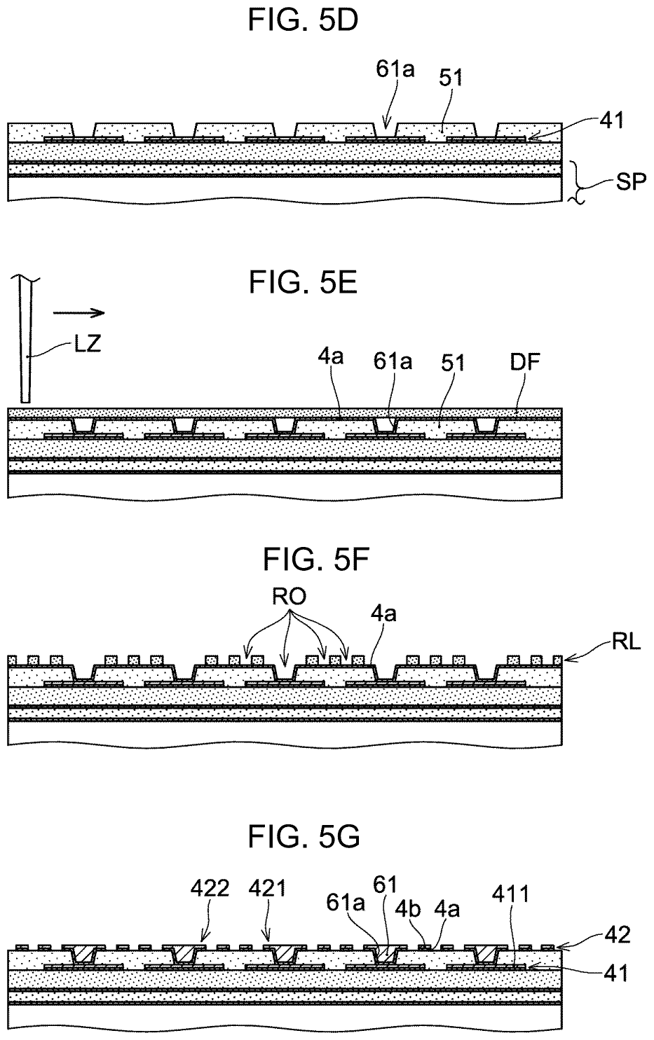

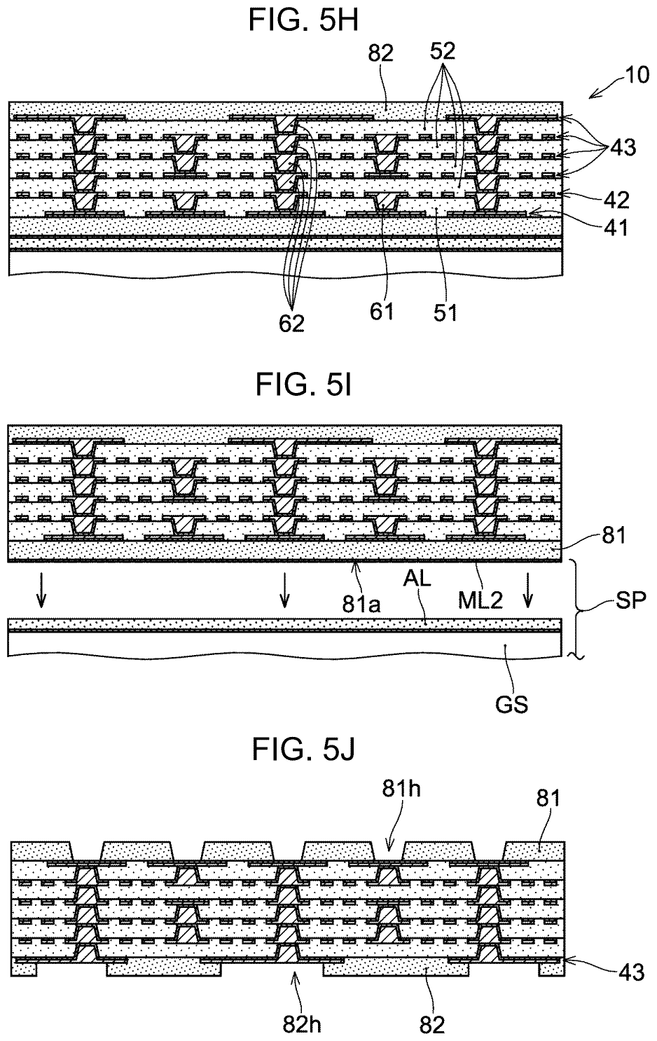

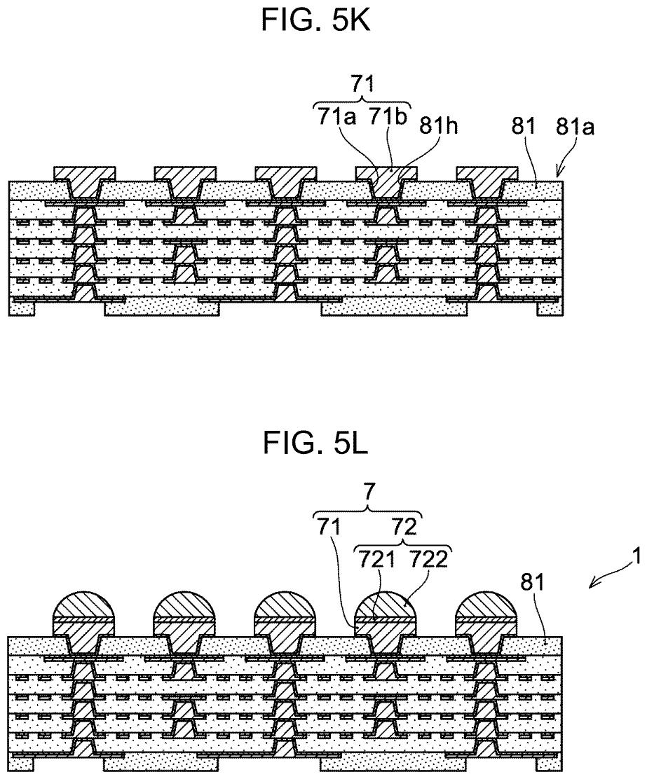

With reference to FIGS. 5A to 5L, an example of a method for manufacturing the wiring substrate of the embodiment is described, using the wiring substrate 1 illustrated in FIG. 1 as an example.

As illustrated in FIG. 5A, a support substrate (SP) is prepared, which includes a core layer (GS) and metal film layers (ML1, ML2) laminated on each of two surfaces of the core layer (GS). The core layer (GS) is constituted by, for example, a glass material or a glass epoxy material. The metal film layers (ML1, ML2) are each, for example, a single-layer or multi-layer metal film formed by electroless plating or sputtering using materials such as copper and titanium or the like. The metal film layer (ML1) and the metal film layer (ML2) are bonded together by, for example, an adhesive layer (AL) constituted by an adhesive whose adhesiveness changes upon exposure to light.

In the following description, a side closer to the core layer (GS) of the support substrate (SP) is also referred to as “lower” or “lower side,” and a side farther from the core layer (GS) is also referred to as “upper” or “upper side.” Therefore, of each of the elements constituting the wiring structure, a surface facing the support substrate (SP) is also referred to as a “lower surface,” and a surface facing the opposite side with respect to the support substrate (SP) is also referred to as an “upper surface.”

On a surface of the metal film layer (ML2) of the prepared support substrate (SP), the solder resist layer 81 is formed, as illustrated in FIG. 5A. For example, a resin film made of a polyimide resin or an epoxy resin is formed by supplying a photosensitive epoxy resin or polyimide resin onto the surface of the metal film layer (ML2) using a method such as spraying, coating, or laminating. The solder resist layer 81 is formed by curing this resin film through ultraviolet irradiation or a heat treatment.

As illustrated in FIG. 5B, the first metal film (4a) and the second metal film (4b) are formed on the surface (81b) of the solder resist layer 81 on the opposite side with respect to the support substrate (SP). First, the first metal film (4a), made of a metal such as copper, is formed over the entire surface (81b) of the solder resist layer 81 by electroless plating or sputtering. After that, a resist film (RF) is formed on the first metal film (4a) by laminating a dry film. In the resist film (RF), openings (RFO) corresponding to formation regions of conductor patterns, such as the conductor pads 411 (see FIG. 5C) included in the conductor layer 41 (see FIG. 5C), are formed using a photolithography technology or the like. Then, by electrolytic plating using the first metal film (4a) as a power feeding layer, the second metal film (4b) is formed in the openings (RFO). After the formation of the second metal film (4b), the resist film (RF) is removed. Furthermore, portions of the first metal film (4a) exposed by the removal of the resist film (RF) are removed.

As a result, as illustrated in FIG. 5C, the conductor layer 41 including individually electrically separated conductor pads 411 at desired positions is obtained. In a manufacturing process of the wiring substrate of the embodiment, such as the wiring substrate 1 illustrated in FIG. 1, a short-circuit check between conductor patterns, such as the conductor pads 411 included in the conductor layer 41, can be performed at the point when the formation of the conductor layer 41, as illustrated in FIG. 5C, is completed. In other words, in the formation of the conductor layer 41, for example, the metal film layer (ML2) of the support substrate (SP) is not used as a power feeding layer; instead, the first metal film (4a) formed on the solder resist layer 81 is used as a power feeding layer. And, portions of the first metal film (4a) that do not constitute the conductor patterns of the conductor layer 41 have already been removed by the point when the formation of the conductor layer 41 is completed. That is, the individual conductor patterns of the conductor layer 41 are already electrically separated from each other at the point when the formation of the conductor layer 41 is completed. Therefore, a short-circuit check between the conductor patterns of the conductor layer 41 can be performed at the point when the formation of the conductor layer 41 is completed, that is, before proceeding to the next processes, such as the formation of the insulating layer 51 (see FIG. 5D). Therefore, a short-circuit defect can be detected early. This can save labor and costs that would otherwise be incurred when work-in-progress items with short-circuit defects continued to flow through the process. And, a wiring substrate of good quality can be manufactured.

As illustrated in FIG. 5D, the insulating layer 51 covering the conductor layer 41 is formed. The insulating layer 51 is formed, for example, from a thermosetting resin such as an epoxy resin, a BT resin, or a phenol resin, and a thermoplastic resin such as a fluorine resin or LCP (liquid crystal polymer). The insulating layer 51 is formed by thermocompression bonding these resins, which have been molded into a film-like shape. In the insulating layer 51, through holes (61a) are formed at positions where the via conductors 61 (see FIG. 5G) are to be formed, for example, by irradiation with CO₂ laser, excimer laser, or the like. Although not illustrated, the formation of the through holes (61a) may be performed while protecting the upper surface of the insulating layer 51 with a protective film such as a polyethylene terephthalate (PET) film. Preferably, after the formation of the through holes (61a), resin residues (smear) that are like to occur in the through holes (61a) are removed by dry desmearing using a plasma gas or wet desmearing using a permanganate solution.

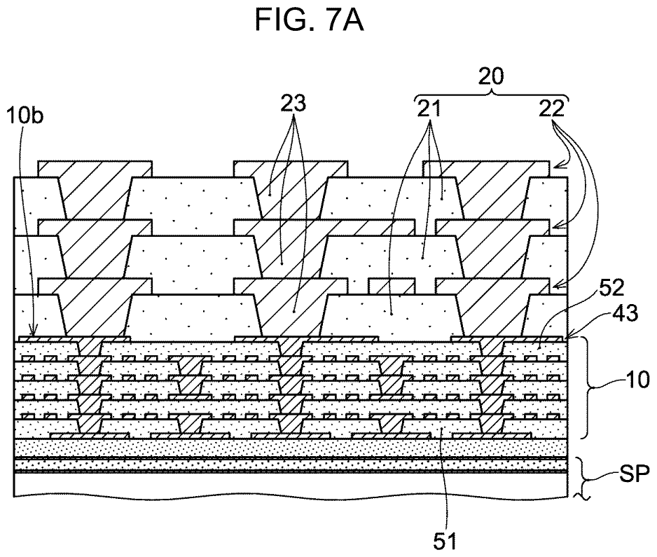

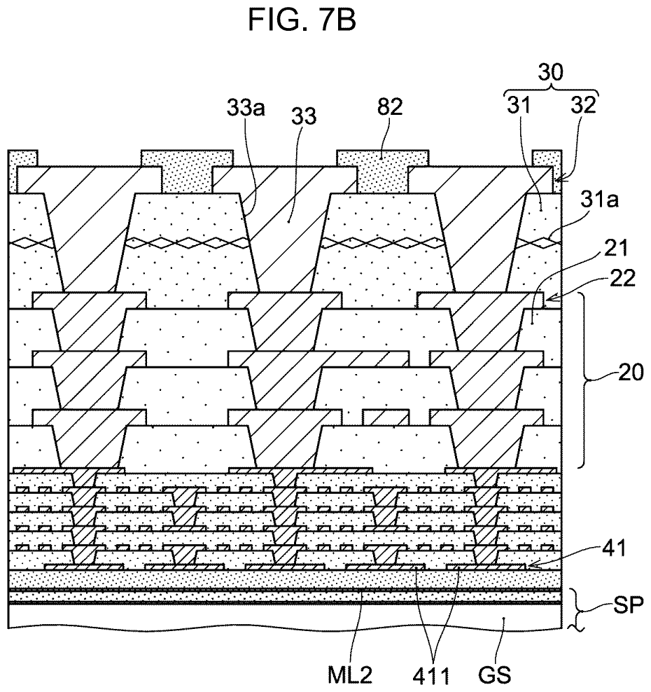

In FIG. 5D, as well as in FIGS. 5E to 5I, 7A, and 7B to be referenced below, a state after each process is illustrated only for one surface side of the support substrate (SP), while illustration of a state on the other side is omitted. However, on the surface of the support substrate (SP) on the side where illustration is omitted, insulating layers and conductor layers may be formed in the same manner as on the illustrated side, or it is also possible that such conductor layers and insulating layers are not formed.

As illustrated in FIG. 5E, after the formation of the through holes (61a), the first metal film (4a) constituting the conductor layer 42 (see FIG. 5G) is formed on inner walls of the through holes (61a) and on the surface of the insulating layer 51 by electroless plating or sputtering or the like. Then, for example, a dry film (DF) containing a photosensitive resin is laminated on the first metal film (4a). The dry film (DF) is subjected to exposure and development processes. The exposure of the dry film (DF) is performed, for example, by direct imaging, in which laser (LZ) is irradiated along patterns corresponding to the conductor patterns to be provided in the conductor layer 42. It is also possible that the exposure of the dry film (DF) is performed using an exposure mask having openings corresponding to the conductor patterns to be provided in the conductor layer 42.

As a result of the development process on the exposed dry film (DF), as illustrated in FIG. 5F, a plating resist (RL) having openings (RO) corresponding to the conductor patterns to be provided in the conductor layer 42 (see FIG. 5G) is formed.

After the formation of the plating resist (RL), the second metal film (4b) (see FIG. 5G) including an electrolytic plating film is formed in the openings (RO) of the plating resist (RL) by electrolytic plating using the first metal film (4a) as a power feeding layer. After that, the plating resist (RL) is removed, for example, using an alkaline peeling solution. Furthermore, portions of the first metal film (4a) exposed by the removal of the plating resist (RL) are removed, for example, by etching.

As a result of the partial etching of the first metal film (4a), as illustrated in FIG. 5G, the conductor layer 42 constituted by the first metal film (4a) and the second metal film (4b), including the conductor pads (421, 422), is obtained. The via conductors 61 are formed in the through holes (61a). In the manufacturing process of the wiring substrate of the embodiment, also after the formation of the conductor layer 42, a short-circuit check can be performed between the conductor patterns of the conductor layer 42, which are respectively connected to the conductor patterns of the conductor layer 41, such as the conductor pads 411.

As illustrated in FIG. 5H, using methods similar to the methods for forming the insulating layer 51, the conductor layer 42, and the via conductors 61 described above, a desired number of insulating layers 52 and conductor layers 43 (four layers each in FIG. 5D), as well as via conductors 62 penetrating the respective insulating layers, are further formed. The formation of the build-up part 10 is completed. In the manufacturing process of the wiring substrate of the embodiment, also after the formation of each conductor layer 43, a short-circuit check can be performed between the conductor patterns of the conductor layer 43, which are respectively connected to the conductor patterns of the conductor layer 41. Therefore, a short-circuit defect can be detected early. It may be possible to save labor and costs that would otherwise be incurred when work-in-progress items with short-circuit defects continued to flow through the process. And, it is thought that a wiring substrate of good quality can be manufactured.

After the formation of the desired number of conductor layers 43, the solder resist layer 82 is formed on the uppermost conductor layer 43 and insulating layer 52. The solder resist layer 82 is formed, for example, using a photosensitive polyimide resin or epoxy resin, using any method such as spraying, laminating, coating, or the like. It is also possible that the solder resist layer 82 is formed not immediately after the formation of the desired number of conductor layers 43, but after the removal of the core layer (GS) of the support substrate (SP), which will be described below with reference to FIG. 5I.

As illustrated in FIG. 5I, the core layer (GS) of the support substrate (SP) is removed. The lower surface of the metal film layer (ML2) of the support substrate (SP) is exposed. The core layer (GS) is removed, for example, by peeling the metal film layer (ML2) from the adhesive layer (AL) after the adhesive layer (AL) has been softened by laser irradiation. Then, the metal film layer (ML2) is removed by etching, and the surface (81a) of the solder resist layer 81 is exposed.

As illustrated in FIG. 5J, the openings (81h) are formed in the solder resist layer 81, and the openings (82h) are formed in the solder resist layer 82. FIG. 5J, as well as FIGS. 5K and 5L, are drawn such that the solder resist layer 81 is positioned on the upper side and the solder resist layer 82 is positioned on the lower side. The openings (81h) and the openings (82h) are formed, for example, by photolithography, including exposure and development processes, or by laser irradiation, or the like. The openings (81h) are formed in regions where the metal posts 7 (see FIG. 5L) will be formed in a subsequent process. The openings (82h) are formed in regions that expose desired regions of the conductor pads of the conductor layer 43 covered by the solder resist layer 82.

As illustrated in FIG. 5K, the base plating layer 71 of the metal posts 7 (see FIG. 5L) is formed. As an example, the base plating layer 71 is formed using a method similar to the previously described method for forming the conductor layer 42. In other words, the third metal film (71a), made of copper, for example, is formed on inner walls of the openings (81h) and on the entire surface (81a) of the solder resist layer 81 by electroless plating, sputtering, or the like. Then, a dry film (not illustrated) is laminated on the third metal film (71a), and a plating resist is formed by providing openings in regions of the dry film corresponding to formation regions of the base plating layer 71 above the openings (81h) by exposure and development. Within the openings of the plating resist, for example, the fourth metal film (71b), made of copper, is formed by electrolytic plating using the third metal film (71a) as a power feeding layer. After that, the plating resist is removed, and further, portions of the third metal film (71a) exposed by the removal of the plating resist are removed, for example, by etching. As a result, the base plating layer 71, as illustrated in FIG. 5K, which includes the third metal film (71a) and the fourth metal film (71b) and fills the openings (81h), is formed.

As illustrated in FIG. 5L, the top plating layer 72 of the metal posts 7 is formed on the base plating layer 71. For example, the lower layer 721 of the top plating layer 72 is formed on the exposed surface of the base plating layer 71 by electroless plating of a metal such as nickel. Then, the upper layer 722 of the top plating layer 72, constituted by a metal such as solder, is formed on the lower layer 721, for example, by electroless plating. As a result, the metal posts 7, as illustrated in FIG. 5L, which each include the base plating layer 71 and the top plating layer 72 and protrude from the solder resist layer 81, are formed. Through the above processes, the wiring substrate 1 of the embodiment illustrated in FIG. 1 is completed.

When the wiring substrate (1a) of the modified example illustrated in FIG. 4 is manufactured, after the removal of the core layer (GS) of the support substrate (SP) as described with reference to FIG. 5I, the processes described with reference to FIGS. 5J to 5L are carried out without removing the metal film layer (ML2). As a result, the base plating layer 71 of the metal posts 7, which includes a portion of the metal film layer (ML2) as the fifth metal film (71c), is formed, and the wiring substrate (1a) including such metal posts 7 is manufactured. The unwanted portions of the metal film layer (ML2) may be removed, for example, by etching, together with the portions of the third metal film (71a) that are exposed without being covered by the fourth metal film (71b), in the process described with reference to FIG. 5K.

### Second Embodiment

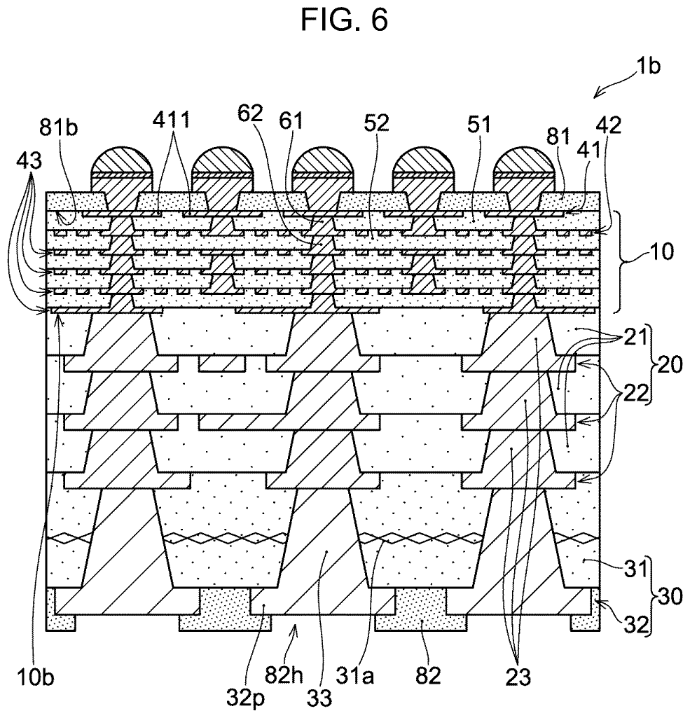

FIG. 6 illustrates a cross-sectional view of a wiring substrate (1b) of a second embodiment. As illustrated in FIG. 6, the wiring substrate (1b) includes, in addition to the build-up part 10 (first build-up part), solder resist layer 81, and metal posts 7 included in the wiring substrate 1 of FIG. 1, a build-up part 20 (second build-up part) and a build-up part 30 (third build-up part). The build-up part 20 is constituted by alternately laminated insulating layers 21 and conductor layers 22. The build-up part 30 is constituted by an insulating layer 31 and a conductor layer 32.

The build-up part 20 is laminated on the second surface (10b) of the build-up part 10. The build-up part 30 is laminated on a surface of the build-up part 20 on the opposite side with respect to the build-up part 10 side. The solder resist layer 82 is formed not on the second surface (10b) of the build-up part 10, but on a surface of the build-up part 30 on the opposite side with respect to the build-up part 10 side.

In the insulating layers 21 of the build-up part 20, via conductors 23 are formed, which penetrate each insulating layer 21 and connect opposing conductor layers across each insulating layer 21. The conductor layers 22 can each include desired conductor patterns. In the insulating layer 31 of the build-up part 30, via conductors 33 are formed, which penetrate the insulating layer 31 and connect the conductor layer 32 to the conductor layer 22 of the build-up part 20. The conductor layer 32 can include desired conductor patterns. In the example of FIG. 6, the conductor layer 32 includes conductor pads (32p). The conductor pads (32p) are exposed from the openings (82h) of the solder resist layer 82.

The surface of the wiring substrate (1b) on the build-up part 30 side is a surface that, during use of the wiring substrate (1b), connects to an external member, such as a motherboard of an electronic device in which the wiring substrate (1b) is employed. The conductor pads (32p) may be connected to any substrate, electrical component, mechanical component, or the like.

The insulating layers 21 constituting the build-up part 20 and the insulating layer 31 constituting the build-up part 30 can be formed using the same insulating resin as the insulating layer 51 and insulating layers 52 of the build-up part 10. Although not illustrated, the insulating layers 21 may each include a core material (reinforcement material) made of glass fiber or aramid fiber. In the example of FIG. 6, the insulating layer 31 of the build-up part 30 includes a core material (31a) made of glass fiber. The insulating layers 21 and the insulating layer 31 can further contain an inorganic filler (not illustrated) made of fine particles of silica (SiO₂), alumina, mullite, or the like. In the wiring substrate (1b), a thickness of each of the insulating layers 21 may be greater than a thickness of each of the insulating layer 51 and insulating layers 52, and a thickness of the insulating layer 31 may be greater than the thickness of each of the insulating layers 21.

The conductor layers 22, the conductor layer 32, and the via conductors (23, 33) may be formed using any metal, such as copper, in the same manner as the conductor layers, such as the conductor layer 41, and the via conductors (61, 62), of the build-up part 10. The conductor layers 22, the conductor layer 32, and the via conductors (23, 33) may each have, for example, a single-layer structure of only a plating film, or a multilayer structure including two or more metal films formed using any methods such as sputtering or various types of plating. For example, the conductor layers 22 and the conductor layer 32 may each include an electroless plating film and an electrolytic plating film formed on the electroless plating film. In this case, each conductor layer of the build-up part 10, such as the conductor layer 41, may include the first metal film (4a), which is a sputtering film, and the second metal film (4b), which is an electrolytic plating film formed on the first metal film (4a), as described with reference to FIG. 2.

In the wiring substrate (1b), a thickness of each of the conductor layers 22 may be greater than a thickness of each conductor layer of the build-up part 10, such as the conductor layer 41. In other words, a thickness of each of wirings in the conductor layers included in the build-up part 10 may be smaller than a thickness of each of wirings in the conductor layers 22. The thickness of each of the conductor layers included in the build-up part 10 is, for example, about 7 μm or less. The thickness of each of the conductor layers 22 is, for example, 10 μm or more. A thickness of the conductor layer 32 may be greater than the thickness of each of the conductor layers 22, and thus, the thickness of each of wirings in the conductor layer 32 may be greater than the thickness of each of the wirings in the conductor layers 22. The thickness of the conductor layer 32 is, for example, about 20 μm.

In the wiring substrate (1b), a minimum wiring width of wiring patterns in each conductor layer included in the build-up part 10, such as conductor layer 42, may be smaller than a minimum wiring width of wiring patterns included in the conductor layers 22. Further, a minimum inter-wiring distance of the wiring patterns included in each conductor layer of the build-up part 10 may be smaller than a minimum inter-wiring distance of the wiring patterns included in the conductor layers 22. Therefore, it may be possible that wirings that require a high-density formation can be concentrated in the conductor layer 42 of the build-up part 10, while the conductor layers 22 can be provided with wirings under more relaxed wiring rules. As a result, it may be possible to form the build-up part 20 easily and at a lower cost. The wiring patterns included in the conductor layers 22 have a minimum wiring width of about 4 μm and a minimum inter-wiring distance of about 6 μm.

A minimum wiring width of the wiring patterns included in the conductor layer 32 of the build-up part 30 may be greater than the minimum wiring width of the wiring patterns included in the conductor layers 22 of the build-up part 20. Further, a minimum inter-wiring distance of the wiring patterns included in the conductor layer 32 may be greater than the minimum inter-wiring distance of the wiring patterns included in the conductor layers 22. It may be possible that a large current can be passed through the wiring patterns of the conductor layer 32, and further, the conductor layer 32 can be formed more easily and at a lower cost.

Also in the wiring substrate (1b), the conductor layer 41 of the build-up part 10 is formed on the surface (81b) of the solder resist layer 81. Therefore, a short-circuit check between the conductor pads 411 can be performed immediately after the formation of each conductor layer of the build-up part 10. Further, a short-circuit check can be performed between the conductor patterns of the conductor layers (42, 43) that are connected to the conductor patterns of the conductor layer 41, such as the conductor pads 411. Furthermore, in the wiring substrate (1b), during a manufacturing process of the wiring substrate (1b), a short-circuit check can be performed between the conductor patterns of the conductor layers 22 or conductor layer 32, which are connected to the conductor patterns of the conductor layer 41, immediately after the formation of each conductor layer of the build-up part 20 and build-up part 30. Therefore, it is inferred that the wiring substrate (1b) also can have a higher level of good quality compared to conventional wiring substrates.

When the wiring substrate (1b) of the second embodiment illustrated in FIG. 6 is manufactured, after the build-up part 10 is formed up to the state illustrated in FIG. 5H, without forming the solder resist layer 82 and with the support substrate (SP) still attached, the build-up part 20 is formed as illustrated in FIG. 7A. That is, on the conductor layer 43 and insulating layer 52 exposed on the second surface (10b) of the build-up part 10 formed up to the state illustrated in FIG. 5H, a desired number of insulating layers 21 and conductor layers 22 are alternately laminated. In FIG. 7A, three pairs of insulating layers 21 and conductor layers 22 are laminated. In each insulating layer 21, via conductors 23 are formed connecting the conductor layers above and below the insulating layer 21. The insulating layers 21 are formed, for example, using a method similar to the method for forming the insulating layer 51 described above. In the formation of the insulating layers 21, instead of a film-like resin, for example, a resin with a core material molded into a sheet-like shape, such as a prepreg, may be used. The conductor layers 22 and via conductors 23 are formed using any method, for example, a semi-additive method.

In a manufacturing process of the wiring substrate (1b), a short-circuit check between the conductor patterns of each conductor layer 22, which are connected to the conductor patterns of the conductor layer 41, may be performed immediately after the formation of the build-up part 20 illustrated in FIG. 7A and/or immediately after the formation of each conductor layer 22.

As illustrated in FIG. 7B, the build-up part 30 is formed on the insulating layer 21 and conductor layer 22 that constitute the surface of the build-up part 20 on the opposite side with respect to the build-up part 10 side. First, the insulating layer 31 is formed using a method similar to that used for the insulating layers 21. In the example of FIG. 7B, the insulating layer 31 is formed using a prepreg that contains, for example, a core material (31a) constituted by glass fiber. A prepreg with copper foil may also be used. In the insulating layer 31, through holes (33a) are formed at positions where the via conductors 33 will be formed, by laser irradiation or drilling. Then, the conductor layer 32 is formed on the surface of the insulating layer 31, and the via conductors 33 are formed in the through holes (33a). The conductor layer 32 and via conductors 33 are formed using an appropriate method, such as a semi-additive method or a subtractive method.

In a manufacturing process of the wiring substrate (1b), a short-circuit check between the conductor patterns of the conductor layer 32, which are connected to the conductor patterns of the conductor layer 41, such as the conductor pads 411, may be performed immediately after the formation of the conductor layer 32 of the build-up part 30.

After the formation of the build-up part 30, the solder resist layer 82 is formed on the surfaces of the insulating layer 31 and the conductor layer 32 using a photosensitive epoxy resin or polyimide resin. After that, using a method similar to that described with reference to FIG. 5I, the core layer (GS) of the support substrate (SP) is removed, and further, the metal film layer (ML2) is removed. After that, through the processes described with reference to FIGS. 5J to 5L, the wiring substrate (1b) illustrated in FIG. 6 is completed.

The wiring substrate of the embodiment is not limited to those having the structures illustrated in the drawings and those having the structures, shapes, and materials exemplified herein. As described above, the wiring substrate of the embodiment can have any laminated structure. The wiring substrate of the embodiment can have any number of conductor layers and insulating layers. The width of each of the conductor pads 411 may be smaller than the width of each of the conductor pads (421, 422), and may also be smaller than the width of the pad part 712 of the base plating layer 71 of the metal posts 7. The width of the penetrating part 711 of the base plating layer 71 may be smaller than the width of each of the via conductors 61. It is also possible that the penetrating part 711 is not tapered toward the conductor pads 411.

Japanese Patent Application Laid-Open Publication No. 2024-15869 describes a build-up wiring substrate without a core substrate, which is manufactured by alternately forming conductor layers and insulating layers on a surface of a support substrate. A metal film is provided on the surface of the support substrate, and an outermost conductor layer is formed by electrolytic plating using the metal film as a seed layer. A surface (component mounting surface) exposed by removal of the support substrate is constituted by an insulating layer and conductor pads embedded in the insulating layer.

In the wiring substrate described in Japanese Patent Application Laid-Open Publication No. 2024-15869, since the outermost conductor layer is formed on the metal film on the surface of the support substrate, a desired number of conductor layers and insulating layers are sequentially formed while individual conductor patterns in the outermost conductor layer are in a short-circuited state. Therefore, it is thought that an electrical inspection (short-circuit check) for a short circuit between conductor patterns, which are included in the outermost conductor layer and are designed to be separated, cannot be performed until the support substrate and the metal film are removed after the formation of the desired number of conductor layers and insulating layers. Further, it may also be impossible to perform a short-circuit check between conductor patterns of the inner conductor layers connected to the conductor patterns of such an outermost conductor layer. Therefore, visual inspection may become necessary, or even when wiring substrates are formed in multiple product areas on the support substrate, a short-circuit check may only be possible after singulation following the removal of the support substrate. As a result, it may be possible that quality inspection is not efficiently performed. Further, in the wiring substrate of Japanese Patent Application Laid-Open Publication No. 2024-15869, when the conductor pads exposed on the component mounting surface are formed at a narrow pitch, it may be difficult to ensure high connection reliability between these conductor pads and a mounted component.

A wiring substrate according to an embodiment of the present invention includes: a first build-up part that is constituted by laminated conductor layer and insulating layer, and has a first surface and a second surface facing opposite directions with respect to each other; a solder resist layer that is in contact with the first surface of the first build-up part; and a metal post that protrudes from the solder resist layer in the opposite direction with respect to the first surface. The first build-up part includes: a first insulating layer that constitutes the first surface; and a first conductor layer that is formed on a surface of the solder resist layer in contact with the first surface and includes a first conductor pad. The metal post includes a base plating layer connected to the first conductor pad. The base plating layer includes a penetrating part formed in an opening of the solder resist layer and a pad part protruding from the solder resist layer.

According to an embodiment of the present invention, since efficient and sufficient short-circuit checks are possible, it is inferred that the quality of the wiring substrate can be improved. Further, with the metal posts and the solder resist layer, it may be possible to ensure good connection reliability between fine-pitched conductor pads and a mounted component.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a build-up part comprising a conductor layer and an insulating layer;
a solder resist layer formed on the build-up part such that solder resist layer is in contact with a surface of the build-up part; and
a metal post formed on the build-up part such that the metal post is protruding from the solder resist layer,
wherein the build-up part comprises a plurality of conductor layers including the conductor layer and a plurality of insulating layers including the insulating layer such that the conductor layer includes a conductor pad and that the conductor layer is formed on a surface of the solder resist layer and is in contact with a surface of the insulating layer forming the surface of the build-up part, and the metal post includes a base plating layer connected to the conductor pad of the conductor layer in the build-up part such that the base plating layer includes a penetrating portion formed in an opening of the solder resist layer and a pad portion protruding from the solder resist layer.

2. The wiring substrate according to claim 1, wherein the build-up part includes a second conductor pad formed on a second surface of the insulating layer on an opposite side with respect to the surface of the insulating layer forming the surface of the build-up part, and a via conductor penetrating through the insulating layer and connecting the conductor pad and the second conductor pad, the metal post is formed such that a width of the penetrating portion of the base plating layer at an interface with the conductor pad is smaller than a width of the penetrating portion at a surface of the solder resist layer on an opposite side with respect to the build-up part, and the via conductor is formed such that a width of the via conductor at an interface with the conductor pad is smaller than a width of the via conductor at an interface with the second conductor pad.

3. The wiring substrate according to claim 2, wherein the metal post is formed such that the penetrating portion of the base plating layer and the via conductor are tapered in opposite directions with respect to each other.

4. The wiring substrate according to claim 2, wherein the metal post is formed such that a width of the penetrating portion of the base plating layer at the surface of the solder resist layer is greater than the width of the via conductor at the interface with the second conductor pad in the build-up part.

5. The wiring substrate according to claim 2, wherein the conductor layer in the build-up part is formed such that a width of the conductor pad is greater than a width of the pad portion of the base plating layer and the width of the pad portion of the base plating layer in the metal post is greater than a width of the second conductor pad in the build-up part.

6. The wiring substrate according to claim 5, wherein the build-up part and the metal post are formed such that an entire portion of the second conductor pad overlaps with the pad portion of the base plating layer in the metal post, and an entire portion of the pad portion of the metal post overlaps with the conductor pad of the conductor layer in the build-up part.

7. The wiring substrate according to claim 2, wherein the metal post is formed such that a length of the penetrating portion of the base plating layer is greater than a length of the via conductor in the build-up part in a lamination direction of the conductor layer and the insulating layer.

8. The wiring substrate according to claim 1, wherein the metal post includes a top plating layer formed on the base plating layer.

9. The wiring substrate according to claim 1, wherein the build-up part is formed such that the conductor layer includes a first metal film formed in contact with the solder resist layer and a second metal film formed on a surface of the first metal film.

10. The wiring substrate according to claim 1, wherein the build-up part is formed such that the conductor pad of the conductor layer has a surface that is substantially flush with the surface of the insulating layer forming the surface of the build-up part.

11. The wiring substrate according to claim 1, wherein the build-up part is formed such that the conductor layer includes a plurality of wirings having a minimum wiring width of 3 μm or less and a minimum inter-wiring distance of 3 μm or less.

12. The wiring substrate according to claim 1, further comprising:
a second build-up part comprising a conductor layer and an insulating layer and laminated on a second surface of the build-up part on an opposite side with respect to the surface on which the solder resist layer formed.

13. The wiring substrate according to claim 12, wherein the second build-up part is formed such that a minimum wiring width in the conductor layer in the build-up part is smaller than a minimum wiring width in the conductor layer in the second build-up part, a minimum inter-wiring distance in the conductor layer in the build-up part is smaller than a minimum inter-wiring distance in the conductor layer in the second build-up part, and a wiring thickness in the conductor layer in the first build-up part is smaller than a wiring thickness in the conductor layer in the second build-up part.

14. The wiring substrate according to claim 12, wherein the build-up part is formed such that the conductor layer in the build-up part includes a sputtering film and an electrolytic plating film on the sputtering film, and the second build-up part is formed such that the conductor layer in the second build-up part includes an electroless plating film and an electrolytic plating film on the electroless plating film.

15. The wiring substrate according to claim 12, further comprising:
a third build-up part comprising a conductor layer and an insulating layer and laminated on a surface of the second build-up part on an opposite side with respect to the build-up part side.

16. The wiring substrate according to claim 15, wherein the conductor layer in the third build-up part has a wiring thickness that is greater than the wiring thickness in the conductor layer in the second build-up part, and the insulating layer in the third build-up part includes a core material.

17. The wiring substrate according to claim 2, wherein the metal post includes a top plating layer formed on the base plating layer.

18. The wiring substrate according to claim 2, wherein the build-up part is formed such that the conductor layer includes a first metal film formed in contact with the solder resist layer and a second metal film formed on a surface of the first metal film.

19. The wiring substrate according to claim 2, wherein the build-up part is formed such that the conductor pad of the conductor layer has a surface that is substantially flush with the surface of the insulating layer forming the surface of the build-up part.

20. The wiring substrate according to claim 2. wherein the build-up part is formed such that the conductor layer includes a plurality of wirings having a minimum wiring width of 3 μm or less and a minimum inter-wiring distance of 3 μm or less.
